(19) United States
(12) Patent Application Publication
(10) Pub. No.: US 2008/0164611 A1
(43) Pub. Date: Jul. 10, 2008

(54) METHOD FOR MAKING AN INTEGRATED CIRCUIT HAVING A VIA HOLE

(75) Inventors: Harry Hedler, Germering (DE); Franz Kreupl, Muenchen (DE); Roland Irsigler, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/686,004

(22) Filed: Mar. 14, 2007

(30) Foreign Application Priority Data
Jan. 4, 2007 (DE) 10 2007 001 130.1

(51) Int. Cl. H01L 21/00; H01L 25/00

(52) U.S. Cl. 257/739; 438/604; 438/675; 257/E21.001; 257/E25.001

(57) ABSTRACT

An integrated circuit and a method for making an integrated circuit is disclosed. In one embodiment, at least one contact of an electrically conductive material is formed on a substrate. A layer is disposed on the substrate to a predetermined height of the contact. An electrically conductive via hole is provided in the layer by the contact.

### CROSS-REFERENCE TO RELATED APPLICATIONS

This Utility Patent Application claims priority to German Patent Application No. DE 10 2007 001 130.1 filed on Jan. 4, 2007, which is incorporated herein by reference.

### BACKGROUND

Integrated circuits having semiconductors with via holes, i.e. electrical contacts between two layer surfaces, are used in various technological areas. In the area of three-dimensional integration of memory devices, for example, via holes are used in order to connect the individual memory chips to each other. In the fabrication of via holes increased demands exist due to a large aspect ratio of the via holes which are passivated and filled up with an electrically conductive material. Furthermore, the electrical via holes may fulfill a plurality of technical parameters, e.g., the electrical resistance, the electrical capacity and electrical inductivity may be small.

For these and other reasons, there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 2 illustrates a second method for providing a via hole.

FIG. 3 illustrates a third method for providing a via hole.

FIG. 4 illustrates a fourth method for providing a via hole.

FIG. 5 illustrates a fifth method for providing a via hole.

FIG. 6 illustrates a sixth method for providing a via hole.

FIG. 7 illustrates a further embodiment of a substrate.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Embodiments of the present invention provide an integrated circuit and method of making an integrated circuit having a via. One embodiment may in a first process produce the electrical contact. Then the electrical contact is isolated and the layer is subsequently configured. In this manner, electrical contacts may be produced having high aspect ratios, i.e. having a high ratio considering the length of the contact with regard to its diameter.

In a further embodiment, the contact is made of carbon.

In a further embodiment, the contact is made of carbon fibers, for example of carbon tubes. The formation of carbon fibers allows for producing contacts with high Ohmic resistance and a high aspect ratio.

In a further embodiment, the layer consists of a semiconductor material, e.g., of silicon. The forming of the layer of a semiconductor material may be carried out by using a technologically simple process. The use of silicon for forming the layer allows for further integration of mechanical and/or electrical components and circuits, such as memory chips or logic chips in the layer.

In a further embodiment, the silicon may be epitaxially grown on the substrate.

In a further embodiment, a contact may be produced in the shape of a carbon fiber bundle. In this manner, contacts with good electrical properties may be produced using a process technology.

In one embodiment, a silicon oxide layer is deposited on the substrate. A silicon layer is deposited on the silicon oxide layer. A recess with a predetermined area intended for the contact is introduced into the silicon layer, whereby the recess reaches the buried silicon oxide layer. A catalyst material may be introduced into the recess. Subsequently, a carbon is deposited on the catalyst material and the contact is produced. This allows for a well-defined forming of the contact. In a further embodiment, a catalyst material may be used for forming the carbon contact. Suitable catalyst materials may be e.g., nickel, iron or cobalt or combinations thereof.

In a further embodiment of the method, an insulating layer is deposited on the substrate and on the contact in order to insulate the contact. Subsequently, the insulating layer is removed from the substrate surface to a shell surface surrounding the contact. Thereafter, the layer is deposited on the uncovered substrate and on the shell surface.

The carbon may be produced by pyrolysis of carbon-containing gases. Carbon tubes may e.g., be grown by using ethylene and water vapor.

The contact may have a height of 1 to 500 μm and a diameter of 10 nm to 100 μm.

When forming the contact from carbon, in another embodiment the carbon tubes are covered with pyrolytically deposited carbon. Thereby, the spaces between the carbon tubes are filled with carbon. This improves the electric properties of the contact. Furthermore, the carbon tubes are mechanically stabilized. In a further embodiment, the carbon tube contact is doped with charge carriers, thus improving the conductivity of the via holes. In a further embodiment, the pyrolytically deposited carbon is doped with charge carriers. This also improves the electrical properties of the via holes.

In a further embodiment, an electrically conductive layer is formed on the substrate, consisting of a carbon tube felt. The carbon tubes are subsequently infiltrated with a pyrolytically deposited carbon, e.g., by using a carbon layer. The electrically conductive layer is subsequently structured into individual contact bundles, whereby the electrically conductive layer is removed down to the contact bundles. The contact bundles are surrounded by an insulating layer and the semiconductor surface is freed from the insulating layer and cleaned. The spaces between the contact bundles are filled with a semiconductor layer. In this manner, contacts can be produced easily and with an individual geometry.

In a further embodiment of the inventive method, a layer is provided in the form of an insulating layer with at least one contact recess. The insulating layer is applied onto the substrate, whereby the contact is inserted into the contact recess. The space between the contact and the insulating layer is filled by a material. In this manner, a layer including a via hole is produced. The described method offers the advantage that the layer including the contact recess may be fabricated regardless of the substrate including the contact. Thus, various processes may be used for forming the contacts and the layer.

In an embodiment of the method, the space between the contact and the contact recess is filled with a polymer.

In a further embodiment, the carbon fibers are at least partly covered by a pyrolytically deposited carbon.

An embodiment of the present invention relates to a method in which exposed contacts are formed on a substrate and in which at least the shell surfaces of the contacts are subsequently covered by an insulating layer. Then the space between the contacts is filled with a material, such as a semiconductor material. Afterwards, electrical circuits are introduced into the material and the via hole is connected to the electrical circuit in an electrically conductive manner. Subsequently, the substrate may be removed in a further process. By using this procedure, thin material layers, such as semiconductor material including via holes, may be obtained, which may e.g., be electrically contacted in a further process from both sides of the layer. Due to the new procedure, the via holes may have high aspect ratios, since contrary to conventional methods the via holes are not fabricated by producing a via hole and by filling the via hole. In this procedure, at first the contacts for the via holes are fabricated and subsequently the layer in which the via holes are arranged is produced. In this manner, via holes with higher aspect ratios may be produced. During production, various electrically conductive materials may be used. In one embodiment, the contacts are fabricated from carbon, e.g., from carbon tubes. Carbon nano tubes may also be used for this purpose. Contrary to metals, the materials and methods used allow for high temperature further processing, as generally used in semiconductor technology.

FIGS. 1A to 1F illustrate various processes of a first production process. In a first process of FIG. 1A, a substrate 1 is provided. An insulating layer 2 is deposited on the substrate 1. The substrate 1 may be any kind of substrate, e.g., silicon in the shape of a silicon wafer. The insulating layer 2 may be constructed of various materials such as silicon oxide or silicon nitride. Catalyst layers are deposited on the insulating layer 2 in separate basic areas 3. Iron, cobalt or nickel may be used as catalyst. The layers may have a thickness of e.g., 0.5 nm. Due to the arrangement and the shapes of the basic areas 3, the arrangements and cross-sectional areas of the contacts 4 are determined. Electrical contacts 4 are formed on the catalyst areas. For this purpose, various forming processes and various electrically conductive materials may be used. For example, carbon may be grown by a CVD process in the shape of fibers or tubes, e.g., single-wall tubes or multi-wall tubes. The tubes may have a diameter between 0.4 nm and 5 nm in the case of single-wall tubes and between 1 nm and 100 nm in the case of multi-wall tubes, so that reference can be made to nano tubes. Thereby, e.g., a plurality of tubes is formed on a basic area 3. The carbon tubes may be e.g., grown by using an ethylene CVD process, in which ethylene, argon or helium as well as hydrogen or water vapor are used. The deposition process may be carried out within 10 minutes. In the CVD deposition process, e.g., a quartz oven having a diameter of 50 cm or more and a heating zone having a length of 100 cm are used. Water vapor is supplied via a humidifier in the shape of a gas flow. Pure argon (99.99%) or pure helium (99.99%) with 40% hydrogen (99.99%) with a gas flow of 1000 cm³/min may be used as a gas ambient for the CVD process using water vapor. The CVD deposition process may be carried out at a temperature of 750° C. with an ethylene flow of 10 to 150 cm3/min and a water concentration between 20 and 500 ppm during a deposition time of 10 min. As a catalyst, a layer consisting of aluminum oxide having a thickness of 10 nm and iron having a thickness of 1 nm may be applied on a silicon wafer including a silicon oxide layer with a thickness of 1 nm to 1000 nm.

Instead of the described method, use may also be made of other methods in which a contact 4 is formed in the shape of a carbon fiber bundle, in particular carbon tubes. The contacts 4 may also be produced by using other materials which are electrically conductive and may be produced by deposition processes.

After forming the contacts 4, at least the contacts 4 are covered by a second insulating layer, as illustrated in FIG. 1C. Silicon oxide or silicon nitride may for example be used as a second insulating layer 5. For this purpose, the second insulating layer 5 may only be directly deposited on the contacts 4. In a further embodiment, the second insulating layer 5 is extensively deposited on the surfaces of the contacts 4 and on the insulating layer 2. Thereafter, the second insulating layer 5 is removed from the surface of the insulating layer 2, whereby a marginal area remains with a shell layer surrounding the contacts 4. Depending on the selected embodiment, the insulating layer 2 may furthermore also remain covered by the second insulating layer 5.

In a further method process, the result of which is illustrated in FIG. 1D, the spaces between the contacts 4 are filled with a layer 6. The layer 6 may be formed of various materials, such as a semiconductor material. In an embodiment the layer 6 may be silicon. Silicon may be deposited at temperatures of 750 to 800° C. By using a silane flow (SiH₄) of 70 sccm at a procedural pressure of 100 mTorr a deposition rate of 120 nm/h may be achieved. Depending on the used embodiment of the method, the contacts 4 may also be covered by the deposited layer 6 and subsequently the contacts 4 may be uncovered in the upper end region by a removal process, whereby the surface of the layer 6 is configured as a plane surface. Thereby, CMP polishing processes and wet etching processes may be used. The quality of the semiconductor material may be further improved by a heat treatment in the range of 1000 to 1200° C.

Eventually, the layer 6 including the via holes in the shape of the contacts 4, as illustrated in FIG. 1D, may be used for further processes and/or applications.

In one embodiment, as illustrated in FIG. 1E, electrical circuits 7 are incorporated into or onto the layer 6, the electrical circuits being electrically connected to the contacts 4. The electrical circuits may be of various types, such as integrated circuits, for example ASIC circuits or data processing circuits or memory circuits, in particular DRAM memory circuits or flash memory circuits. The memory circuits may also be based on spin effects (MRAM) or phase changes (PCRAM) or resistive components (CBRAM, oxides) for storing or processing data. The electrical circuits 7 may also be operated as simple electrical conductors, e.g., for use in sensors or micromechanical applications, in particular in nanomechanical applications. The circuits 7 may be connected to the contacts 4 via contact lines 23, which may be attached to the upper surface of the layer 6 and/or which may be incorporated into the layer 6, in an electrically conductive manner. In the FIGS. 1E and 1F, the upper region of the layer 6 is illustrated in a hatched manner, in order to illustrate further processing of the layer 6 which is required for the fabrication of the electrical circuit 7.

In a further process, the substrate 1 and the insulating layer 2 may be removed as illustrated in FIG. 1F. In order to remove the substrate 1 and/or the insulating layer 2, known methods such as CMP polishing, wet etching, water jet splitting or abrasive techniques may be employed.

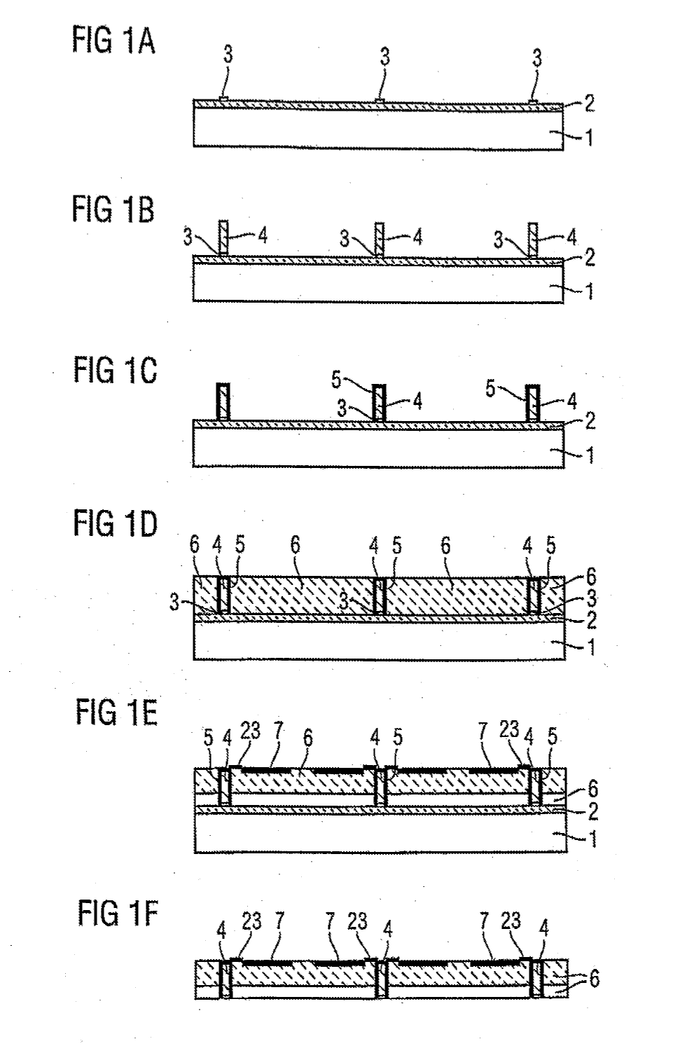

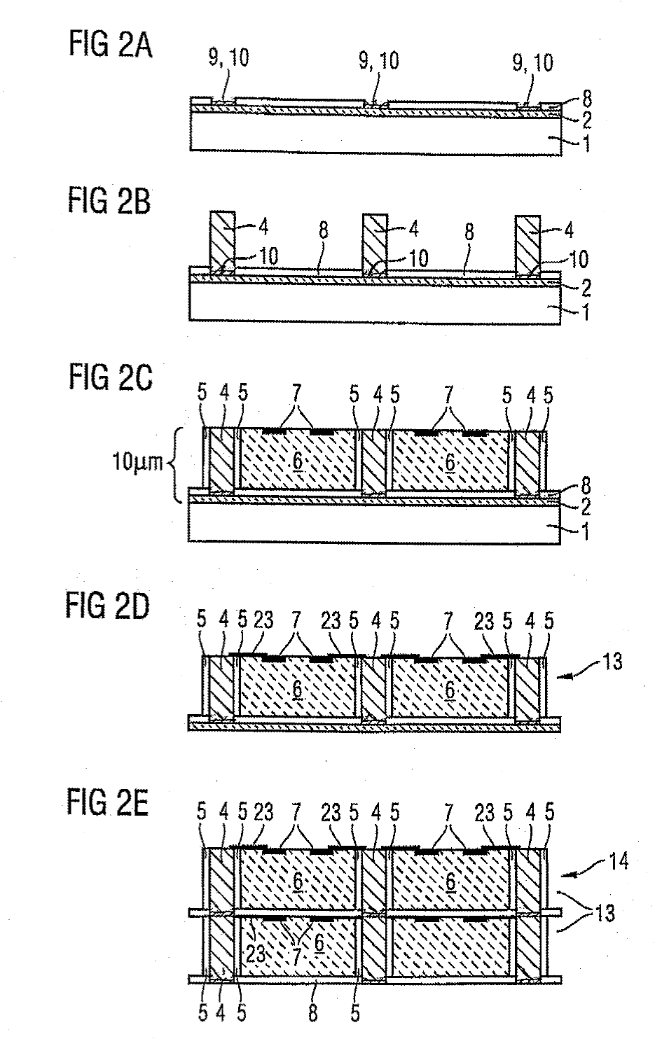

FIGS. 2A to 2E illustrate a further method for forming a layer 6 including at least one via hole. FIG. 2A illustrates a substrate 1 including an insulating layer 2. The insulating layer 2 covers the surface of the substrate 1. The insulation layer 2 may be in the form of an oxide, e.g., a silicon oxide. On the insulating layer 2, a further layer 8 is deposited. The further layer 8 includes recesses 9 into which catalyst layers 10 have been filled. The catalyst layer 10 generally includes a lower thickness than the further layer 8. When forming the further layer 8 in the form of silicon, the recesses 9 may be formed by using a photolithographic masking process and a subsequent etching process. Thereby, the further layer 8 is removed down to the surface of the insulating layer 2. The catalyst layers 10 may for example be circular or rectangular and have a width or a diameter between 10 nm and 100 μm. Materials for the catalyst surfaces 10 may e.g., be nickel, iron or cobalt or combinations thereof. The catalyst materials may either be directly deposited in the recesses 9 or by a lift-off method, as well as structured and inserted into the recesses 9 as catalyst layers 10.

The insulating layer 2 may have a thickness of 10 to 100 nm. Likewise, the further layer 8 may have a thickness of 10 to 200 nm. The catalyst layers 10 may e.g., have a thickness of 0.5 nm and include nickel, iron or cobalt.

In a further process, bundles of carbon tubes are grown on the catalyst layers 10. The height of the bundles may be between 1 and 500 μm, e.g., between 1 and 100 μm. In order to deposit the carbon tubes, various methods may be used, whereby the carbon is deposited e.g., by using ethylene as a carbon source and water vapor, as described in FIG. 1. As a result, contacts 4 are obtained whereby each contact 4 is formed from a carbon tube bundle, as illustrated in FIG. 2B.

In a further process, the surface of the contacts 4 and the surface of the further layer 8 is covered by a second insulating layer 5. The second insulating layer 5 may for example be formed of silicon nitride and/or silicon oxide. The deposited second insulating layer 5 is removed down to the shell surface 5, thereby exposing a part of the surface of the further layer 8. For example, the entire surface of the second layer 8 is exposed down to the basic area of the shell surfaces 5. The second insulating layer 5 may be removed e.g., by back etching. The further layer 8 may also be formed of a crystalline silicon layer.

Subsequently, a layer 6 is formed between the contacts 4, i.e. between the shell surfaces 5. In one embodiment example, the layer 6 is formed as an epitaxially deposited silicon layer, whereby a silicon growth of 150 to 300 nm/min can be achieved. The silicon is e.g., deposited in a low temperature epitaxial process, selectively depositing silicon in an ultra-high vacuum by using a thermo-chemical gas deposition. In this process, disilane (Si₂H₆), hydrogen gas and chlorine gas may be employed at a temperature of 800° C. for deposition in a CVD reactor. Thereby, epitaxially grown silicon layers are generated, whereby layer growth may reach up to 150 nm/min at a temperature of 800° C. and a pressure of about 24 mTorr. In this process, 10% silane and hydrogen and chlorine are used having a minimal silicon:chlorine ratio of 1. Better selectivity with regard to silicon oxide and silicon nitride can be achieved by the described deposition technique, whereby low partial chlorine pressures are sufficient for ensuring selectivity. In this manner, in one embodiment the layer 6 may be formed as an epitaxial silicon layer. Subsequently, electrical circuits 7 are introduced on and/or into the layer 6. This stage of the process is illustrated in FIG. 2C.

In a further process, the substrate 1 and the insulating layer 2 are removed e.g., by an etching process. In this way, a component layer 13 may be obtained. Several component layers 13 may be arranged on top of each other, thus obtaining a stack 14 of component layers 13, as illustrated in FIG. 2E. The individual component layers 13 may be electrically and mechanically connected with each other by adhesive and/or bonding techniques. Thereby, e.g., the electrical contacts of one or of several component layers 13 are connected to each other. Furthermore, the electrical circuits of one component layer 13 or of several component layers 13 may be electrically connected to each other. The component layers 13 may be identical to or different from each other. In this way, a stack 14 of component layers 13 may be fabricated. The contacts 4 of various component layers 13 may be connected to each other via electrical layers or directly. The bonding process may be carried out between wafers, dies on wafers or dies on dies.

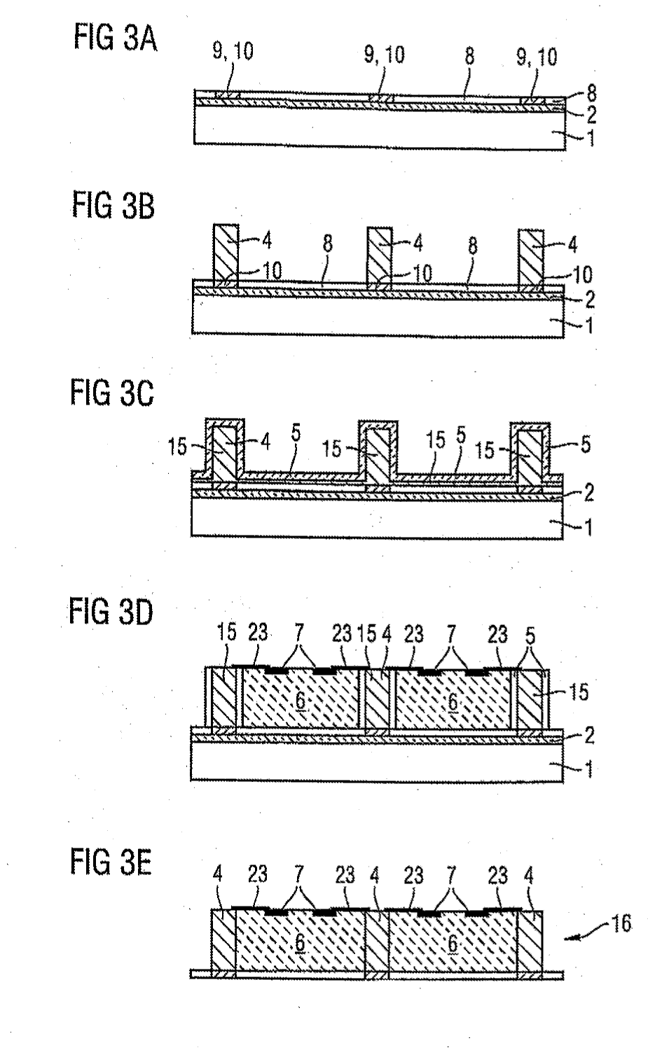

FIGS. 3A to 3F illustrate a third method for fabricating a layer 6 including a via hole.

FIG. 3A illustrates a substrate 1 including an insulating layer 2 and a further layer 8 including recesses 9, into which catalyst layers 10 are incorporated. The arrangement is produced according to FIG. 2A.

Eventually, a contact 4 consisting of carbon fibers, particularly carbon tubes, is disposed on the catalyst layers 10. The contact 4 may be in form of a bundle consisting of a plurality of carbon fibers or carbon tubes. The carbon fibers or the carbon tubes, respectively, are produced according to a method as already explained in conjunction with FIG. 1. This process stage is illustrated in FIG. 3B.

Subsequently, in a further process carbon may be pyrolytically disposed on the contacts 4 in the form of a carbon layer 15. Thereby, the carbon fibers or the carbon tubes, respectively, are covered with carbon. As a result, for example, free spaces between the carbon fibers or carbon tubes may be at least partly or completely filled.

FIG. 3C illustrates an enlarged section of FIG. 3B after depositing the pyrolytic carbon, whereby a contact 4 is illustrated in the shape of a bundle including several carbon tubes 20, whereby the spaces between the tubes are filled with pyrolytic carbon 15. The pyrolytically deposited carbon 15 improves the electrical conductivity as well as the mechanical stability of the fibers. Thereby, the further layer 8 may be covered with a pyrolytically deposited carbon layer 15, as well. The carbon layer 15 may be removed form the surface of the further layer 8. In order to deposit carbon, a precursor, such as methane or acetylene, is used, which pyrolytically decomposes at a temperature of e.g., 750° C. to 1200° C. and is deposited in the form of carbon. The pyrolytically deposited carbon may include an anisotropic layer structure with a high density which is configured laminarily. At low deposition temperatures in the range of 750° C., a layer structure with isotropic properties is formed.

In a further embodiment, the carbon layer 15 may additionally be doped by using charge carriers. The doping may take place during the pyrolytic deposition of the carbon or be carried out after depositing the carbon layer 15. For doping, use can be made of nitrogen, phosphorus, arsenic or boron.

After depositing the carbon layer 15, a second insulating layer 5 is applied. The second insulating layer 5 may consist of silicon nitride or silicon oxide. This process stage is illustrated in FIG. 3D.

In a further embodiment, the carbon layer 15 is removed from the surface of the further layer 8 and the second insulating layer 5 is disposed only subsequently. The second insulating layer 5 is removed from the surface of the further layer 8 to a ring area of surrounding the contacts 4. Eventually, a layer 6 consisting of a material, e.g., silicon, is disposed between the contacts 4. The silicon may e.g., be disposed by a selective, epitaxial deposition method. After this, electrical circuits 7 are disposed in or on the layer 6, respectively. The electrical circuits 7 may be connected to the contacts 4 in an electrically conductive manner via contact lines 23, which are disposed in or on the layer 6. This process stage is illustrated in FIG. 3E.

In a further process, the substrate 1 and the insulating layer 2 are removed. In this way, a second component layer 16 is obtained. This process stage is illustrated in FIG. 3F. By using several second component layers 16, stacks with second component layers 16 may be produced, as has been illustrated by the stack 14 of the component layers 13 in conjunction with FIG. 2E.

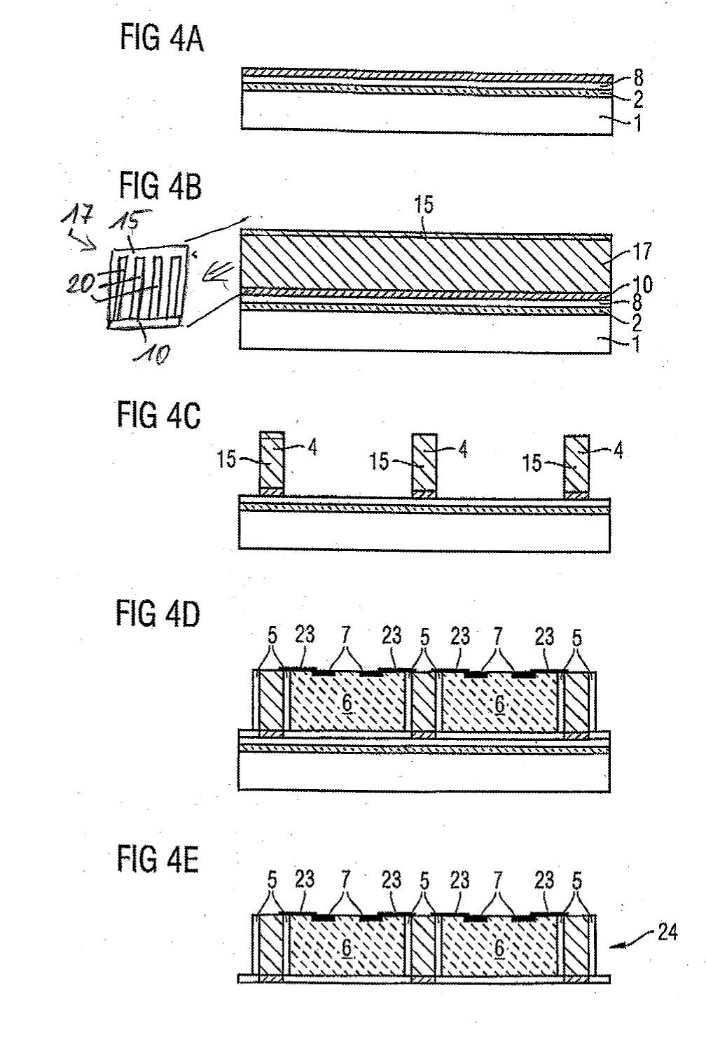

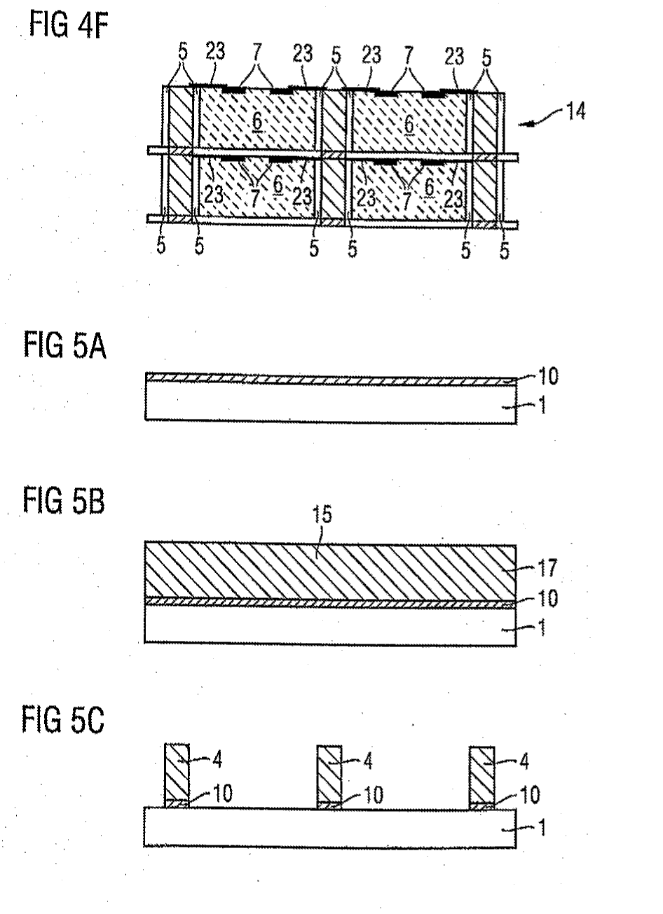

FIG. 4 illustrates a fourth method for fabricating a layer 6 including via holes 4. FIG. 4A illustrates a substrate 1 covered by an insulating layer 2. The insulating layer 2 is covered by a further layer 8. The further layer 8 is covered by a catalyst layer 10. The substrate 1 may be any kind of substrate, e.g., a silicon wafer. The insulating layer 2 disposed on the substrate 1 may e.g., consist of silicon oxide. The insulating layer 2 includes a thickness of 1 to 500 nm. The further layer 8 disposed on the insulating layer 2 may consist of silicon and e.g., have a thickness of 10 to 200 nm. The surface of the layer 8 formed of silicon may be covered by a silicon oxide layer, the thickness of which is in the range of 0.5 to 4 nm. The catalyst layer 10 disposed on the further layer 8 may have a thickness of 0.2 to 3 nm, e.g., 0.5 nm. As a material for the catalyst layer 10, use may be made e.g., of nickel, iron or cobalt.

By using the above-described method, a carbon layer 17 consisting of carbon tubes 20 is grown on the catalyst layer 10. The carbon layer 17 may be a felt of carbon tubes 20. Instead of the carbon tubes 20, carbon fibers may be provided as well. Thereby, the carbon tubes 20 are grown on the catalyst layer 10 and include a length of up to 100 μm. The carbon tubes 20 are arranged essentially perpendicular to the surface of the catalyst layer 10. This process stage is illustrated in FIG. 4B, whereby the carbon tubes are illustrated in an enlarged section. The growing of the layer consisting of carbon tubes is carried out by using the method described in conjunction with FIG. 1 for depositing the contacts 4 made of carbon. The carbon layer 17 consisting of carbon tubes 20 may be partially covered by a pyrolytic carbon 15. The enlarged section of FIG. 4B illustrates the layer of pyrolytically deposited carbon 15 at least partially filling up the spaces between the carbon tubes 20. Depending on the selected embodiment, the spaces may be completely filled by pyrolytically deposited carbon 15.

In a further process, the carbon layer 17 consisting of carbon tubes 20 and the pyrolytic carbon 15 is structured to result in electrical contacts 4, as illustrated in FIG. 4C. For structuring, hard masks may be used in an anisotropic etching process using hydrogen, oxygen or air.

Depending on the selected embodiment, the coating with the pyrolytic carbon 15 may also be carried out after structuring of the carbon layer 17 into bundles of carbon tubes 20.

The contacts 4 which are configured as bundles of carbon tubes 20 are subsequently covered by a second insulating layer 5. The insulating layer 5 and the native oxide layer on the silicon layer 10 are entirely removed from between the contacts 4 of the silicon layer 10 by etching techniques. Thereby, a spacer etching of the insulating layer is employed together with a wet etch clean using diluted hydrofluoric acid. After this, the layer 6 is formed between the contacts 4. Thereby, e.g., silicon may be formed as epitaxial silicon layer according to the method already described above. Subsequently, electrical circuits 7 are disposed in and/or on the layer 6. The electrical circuits 6 may be connected to the contacts 4 in an electrically conductive manner by using the contact lines 23. This process stage is illustrated in FIG. 4D.

In a further process, the substrate 1 and the insulating layer 2 are removed. This process stage is illustrated in FIG. 4E.

From the fourth component layer 24 illustrated in FIG. 4E, stacks 14 including fourth component layers 24 may be produced, as illustrated e.g., in FIG. 4F. The individual component layers 13 may be electrically and mechanically connected to each other by a bonding technique, e.g., wafer bonding. In addition, the electrical circuits 7 of the various fourth component layers 24 may be connected to each other in an electrically conductive manner via the contacts 4.

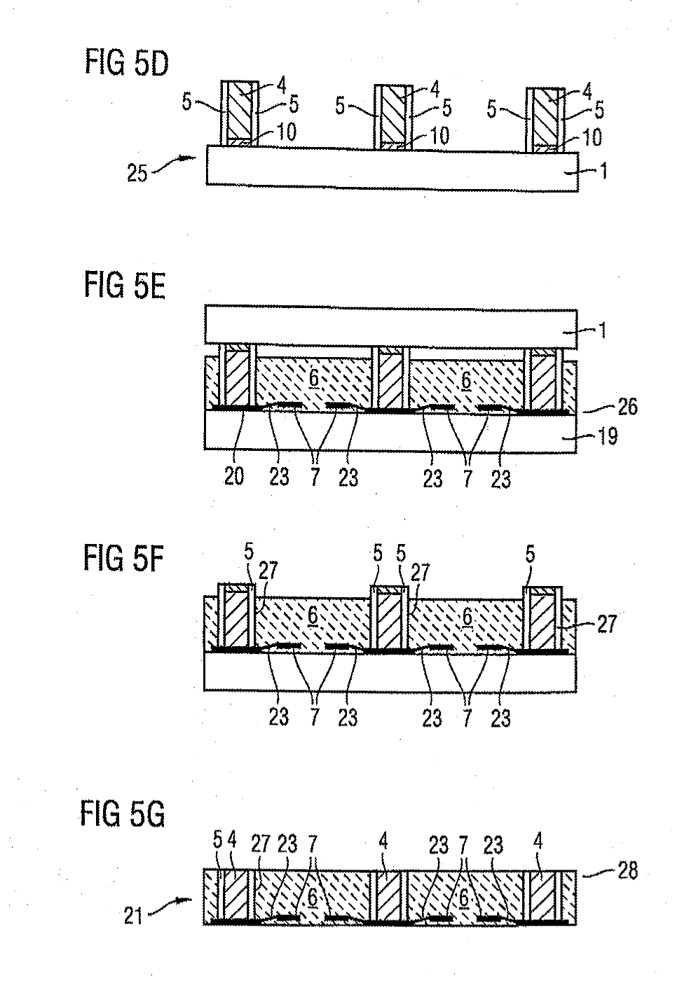

FIGS. 5A to 5G illustrate a fifth method for fabricating a layer 6 including via holes 4. At first a substrate 1 including a catalyst layer 10 is provided, as is illustrated in FIG. 5A. The substrate 1 may have the shape of a carrier wafer with an oxidized silicon surface having a thickness of 0.5 to 4 nm or the shape of an SOI wafer including an insulating intermediate layer having a thickness of 10 to 500 nm as well as an oxidized silicon surface having a thickness of 0.5 to 4 nm. However, other materials for forming the substrate may also be used. The catalyst layer 10 covers the substrate surface 1 and may e.g., include nickel, iron and/or cobalt. The catalyst layer 10 may have a thickness of 0.2 to 1 nm, for example 0.5 nm.

In a following process, a carbon layer 17 consisting of carbon tubes 20 is grown on the catalyst layer 10, as already described in FIG. 4. The carbon layer 17 may be covered, i.e. infiltrated, by a pyrolytic carbon 15, as explained in conjunction with FIG. 4. In this manner, a mechanical stabilization of the carbon tubes 20 may be achieved. Furthermore, the pyrolytic carbon 15 may be doped during the deposition or after the deposition by an ion implant or by in situ doping by adding boron-, phosphorus-, arsenic- or nitrogen-containing gases. This process stage is illustrated in FIG. 5B.

Afterwards, the carbon layer 17 consisting of carbon tubes 20 may be structured to result in individual contacts 4 which are in the shape of carbon tubes 20. For this purpose, e.g., etch masks and anisotropic etching processes are used. Depending on the selected embodiment, the pyrolytic carbon layer 15 may not be deposited on the contacts 4 until the contacts 4 are formed, whereby an ion implant as well as other doping techniques may be carried out. This process stage is illustrated in FIG. 5C. After structuring the contacts 4, the surfaces of the contacts 4 are covered by a second insulating layer 5. The second insulating layer 5 may consist of silicon nitride or silicon oxide.

This process is illustrated in FIG. 5D. FIG. 5D illustrates a partial layer 24, which is inserted into an accordingly shaped second partial layer 26 including a layer 6 with contact recesses 18. This process stage is illustrated in FIG. 5E. The second partial layer 26 includes a second substrate 19 including a layer 6 with already integrated electric circuits 7. Within the layer 6, contact recesses 18 are formed according to the geometry and to the arrangement of the contacts 4. As described above, the layer 6 may consist of silicon or other materials. During assembly, the contacts 4 are inserted into the contact recesses 18. Depending on the selected embodiment, the contacts 4 may be inserted into the contact recesses 18 with or without a second insulating layer 5. In the area of the contact recesses 18, an electrically conductive layer 30 is formed on the second substrate 19. The conductive layer 30 is connected to the electric circuits 7 in an electrically conductive manner either directly or via a contact line 23. This process stage is illustrated in FIG. 5E.

In a further process, the substrate 1 is removed and an arrangement according to FIG. 5F is obtained. Cavities between the electrical contact 4 and the layer 6 or between the second insulating layer 5 and the layer 6, respectively, may be filled by a liquid insulation material 27, e.g., by a polymer. Thereafter, the second substrate 19 may be removed as well. Furthermore, the upper region of the contacts 4 on which the catalyst layer 16 is still arranged, may be removed. In this manner, a third component layer 28 is obtained, as illustrated in FIG. 5G.

The contacts 4 may be connected in a reflow soldering process by using the solder of the conductive layer 20. In this way, the electrical contact between the conductive layers 20 and the contacts 4 is improved.

By using the method described in conjunction with FIGS. 5A to 5G, it is possible to obtain a layer with via holes including contacts 4 with a high aspect ratio, whereby the contacts 4 and the layer 6 having the contact recesses 18 may be produced in various processes and independently from each other. This renders the fabrication process more flexible.

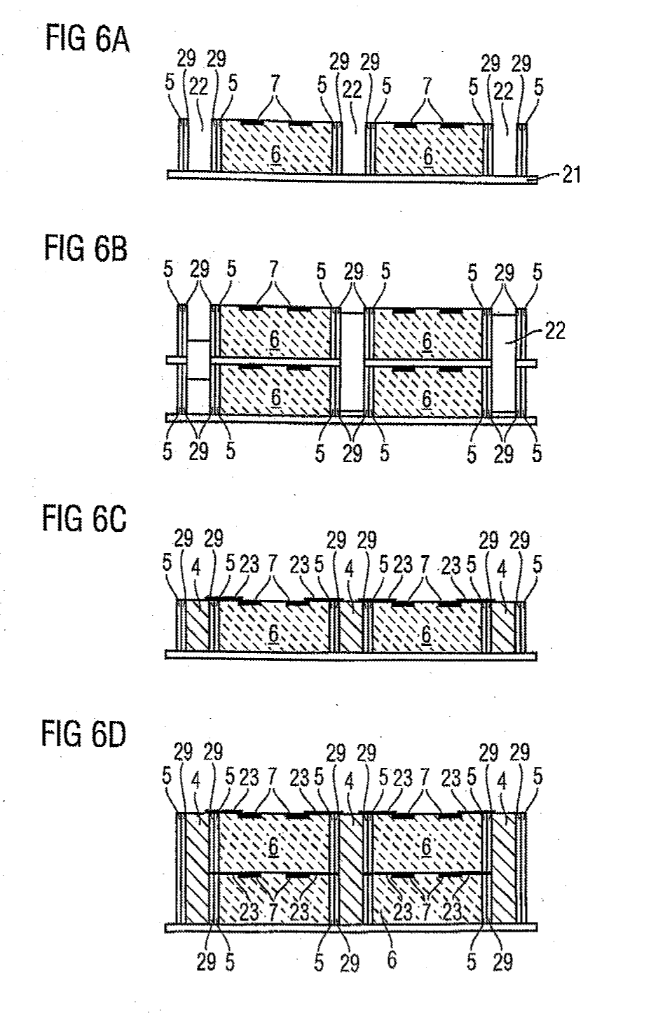

FIG. 6 illustrates a further method for fabricating a layer 6 including a via hole with contacts 4, a layer 6 having electric circuits 7 and contacts 4 being produced by using the already described method. Subsequently, in a following process the contacts 4 are removed and second contact recesses 22 are obtained. When forming the contacts 4 in the shape of bundles of carbon tubes, the bundles of carbon tubes may be removed by using oxygen plasma or hydrogen plasma. This process stage is illustrated in FIG. 6A. In order to simplify the process, prior to depositing the second insulating layer 5 a further conductive coating 29 consisting of a tantalum layer and/or of a tantalum nitride layer is deposited on the contacts 4. Other refractory, conductive materials may be deposited as well. Thereupon, an electrically conductive back plate 21 is applied on a bottom side of the layer 6, being e.g., made of metal such as titan or titan nitride.

The layer 6 already includes electric circuits 7. In this manner, a layer 6 including electric circuits 7 and second contact recesses 22 is obtained.

In a further process, the second contact recesses 22 are filled with an electrical material, such as copper by electro-plating. In this manner, a layer 6 with contacts 4 is obtained, as illustrated in FIG. 6B. The contacts 4 are connected to the electric circuits 7 via contact lines 23.

Depending on the selected embodiment, several layers may be arranged on top of each other in the form of a stack. This embodiment is illustrated in FIG. 6C. FIG. 6D illustrates a stack with filled-up second contact recesses 22 representing electrical contacts 4.

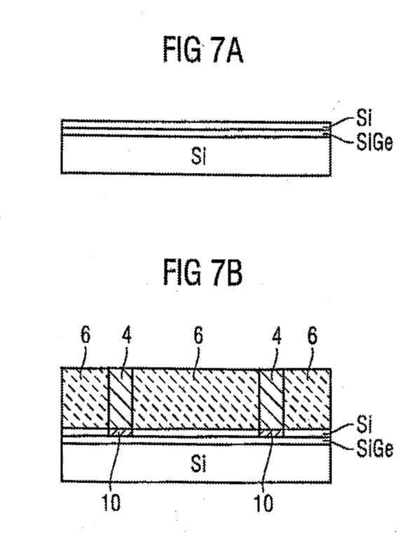

FIG. 7A illustrates a further embodiment using silicon as a substrate 1, on which a silicon-germanium-layer followed by a silicon layer is arranged, the silicon layer corresponding to the layer 8. The silicon layer is epitaxially grown on the silicon-germanium-layer. The silicon-germanium-layer is a separating layer. In this way, an inexpensive structure may be provided instead of an SOI substrate. Depending on the used embodiment, other structures in which silicon is epitaxially grown may also be employed. After depositing the contacts 4 as described in the preceding Figures, silicon is epitaxially disposed on the silicon layer. In this manner, an epitaxial silicon layer including contacts 4 is obtained, the contacts 4 having a high aspect ratio. The silicon-germanium-layer may have a thickness of 10 to 100 nm.

FIG. 7B illustrates a substrate including a silicon, a SiGe and a silicon layer, the catalyst layers 10 being disposed on the SiGe layer, whereby contacts 4 are grown on the catalyst layers 10, particularly consisting of carbon tubes, and whereby a layer 6 is formed between the contacts 4. The carbon tubes may be covered and infiltrated by pyrolytically disposed carbon. The silicon-germanium-layer may be selectively dissolved with regard to the silicon layers by a wet etching process. Thereby, a thin silicon layer having via holes 4 is obtained.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A method making an integrated circuit comprising:
forming at least one contact on a substrate from electrically conductive material; and
disposing a layer on the substrate up to a predetermined level of the contact, including providing an electrically conductive via hole in the layer by the contact, the via hole being guided from one side of the layer to an opposite side.

2. The method of claim 1, comprising forming electrical circuits on or in the layer.

3. The method of claim 1, comprising wherein the contact at least partially consisting of carbon.

4. The method of claim 3, comprising wherein the contact being formed of carbon fibers.

5. The method of claim 1, comprising disposing a contact in the form of a carbon fiber bundle.

6. The method of claim 4, comprising forming a carbon tube as a carbon fiber.

7. The method of claim 1, comprising applying a catalyst material for disposing carbon on a predetermined area on the substrate, whereby the carbon is disposed and the contact produced by the catalyst material.

8. The method of claim 1, comprising disposing the layer from a semiconductor material.

9. The method of claim 8, comprising forming the layer from silicon.

10. The method of claim 9, comprising disposing the silicon epitaxially.

11. The method of claim 1, comprising disposing the layer having a thickness larger than the height of the contact, and removing the layer down to an upper end of the contact.

12. The method of claim 1, comprising disposing a silicon oxide layer on the substrate, disposing a silicon layer on the silicon oxide layer, introducing a recess for the contact into the silicon layer reaching the buried silicon oxide layer, disposing a catalyst material for disposing the carbon in the recess, and disposing a carbon tube onto the catalyst material and forming the contact.

13. The method of claim 12, comprising disposing the silicon oxide layer having a thickness of 1 to 500 nm.

14. The method of claim 12, comprising disposing the silicon layer having a thickness between 10 and 200 nm.

15. The method of claim 1 1, comprising wherein at least one of the materials selected from the group consisting of nickel, iron or cobalt is disposed as a catalyst.

16. The method of claim 1, comprising disposing an isolating layer on the substrate and on the contact for isolation the contact, whereby the isolating layer is subsequently removed from the surface of the substrate down to a shell surface surrounding the contact, and the contact remaining covered by the isolating material.

17. The method of claim 16, comprising wherein the isolating layer consisting of silicon nitride or silicon oxide.

18. The method of claim 1, comprising forming the contact of a carbon tube and disposing the carbon tube by means of ethylene and water vapor.

19. The method of claim 1, comprising wherein the contact having a height of 1 to 500 μm.

20. The method of claim 1, comprising wherein the contacting having a diameter of 10 nm to 100 μm.

21. The method of claim 1, comprising forming the contact of carbon tubes and covering the carbon by a carbon disposed via pyrolysis.

22. The method of claim 1, comprising wherein the contact consisting of carbon and the carbon being doped by charge carriers.

23. The method of claims 20, comprising wherein the carbon disposed by pyrolysis is doped.

24. The method of claim 1, comprising forming an electrically conductive layer of carbon fibers on the substrate, the electrically conductive layer being patterned to result in individual contacts, and covering the contacts with an isolation layer.

25. The method of claim 24, comprising infiltrating the electrically conductive layer of carbon fibers with pyrolytically disposed carbon prior to patterning of the contacts.

26. The method of claim 24, comprising forming the carbon fibers as carbon tubes.

27. The method of claim 1, comprising providing one layer in the form of an isolation layer with at least one contact recess, applying the isolation layer on the substrate, disposing the contact in the contact recess and an intermediate space between the contact and filling the isolation layer with a material.

28. The method of claim 27, comprising forming the isolation layer on a carrier, removing the carrier after connecting the isolation layer to the substrate.

29. The method of claim 27, comprising filling the intermediate space with a polymer.

30. The method of claim 27, comprising forming an electrical circuit in or on the isolation layer, connecting the electrical circuit to at least one of the contacts in an electrically conductive manner.

31. The method of claim 1, comprising using the contact as a sacrificial contact, removing the contact upon forming the isolating layer and a contact recess being obtained, filling the contact recess with a conductive material and obtaining a second electrical contact.

32. The method of claim 1, comprising:
covering the contact by a tantalum/tantalum nitride layer; and
disposing the isolation layer on the tantalum/tantalum nitride layer.

33. An integrated circuit device comprising:
a substrate having a contact consisting of a carbon fiber bundle, the bundle being embedded in a layer as a via hole.

34. The device of claim 33, comprising wherein the bundle has a diameter of less than 100 μm.

35. The device of claim 33, comprising wherein several layers having via holes are arranged as a stack.

36. The device of claim 33, comprising wherein the carbon fibers being doped with impurities.

37. The device of claim 33, comprising wherein the carbon fibers being formed as carbon tubes.

38. The device of claim 33, comprising wherein the carbon fibers being at least partially covered with a carbon fabricated by pyrolysis.

39. The device of claim 38, comprising wherein the intermediate spaces between the carbon fibers being filled with pyrolytically disposed carbon.

40. The device of claim 33, comprising wherein the device being produced as a part of an electronic circuit.

41. The device of claim 33, comprising wherein the device being produces as a part of a memory circuit.

42. The device of claim 33, comprising wherein the isolating layer being formed as a shell layer surrounding the bundle, the shell layer being surrounded by a layer of disposed silicon.

43. The device of claim 42, comprising wherein the silicon being epitaxially disposed silicon.

44. The device of claim 33, comprising wherein the bundle having a height between 1 μm and 100 μm.

45. The device of claim 33, comprising wherein the bundle having a diameter of 10 nm to 100 μm.

46. The device claim 33, comprising wherein several layers having contacts are provided as via holes, the several layers being mechanically connected to each other by a bonding connection and the contacts of the layers being electrically connected to each other.

47. An integrated circuit comprising:
a substrate;
at least one contact formed on the substrate from electrically conductive material;
a layer disposed on the substrate up to a predetermined level of the contact, including an electrically conductive via hole in the layer by the contact, the via hole being guided from one side of the layer to an opposite side.

48. The integrated circuit of claim 47, comprising:
electrical circuits formed on or in the layer.

49. The integrated circuit of claim 47, comprising wherein the contact at least partially consisting of carbon.

50. The integrated circuit of claim 49, comprising wherein the contact being formed of carbon fibers.

51. The integrated circuit of claim 47, comprising a contact disposed in the form of a carbon fiber bundle.

52. The integrated circuit of claim 50, comprising a carbon tube formed as a carbon fiber.

53. The integrated circuit of claim 47, comprising:
a silicon oxide layer on the substrate;
a silicon layer disposed on the silicon oxide layer;
a recess introduced for the contact into the silicon layer reaching the buried silicon oxide layer; and
a catalyst material for disposing the carbon in the recess, and a carbon tube disposed onto the catalyst material and forming the contact.
